(19) United States
(12) Patent Application Publication
(10) Pub. No.: US 2025/0274540 A1
(43) Pub. Date: Aug. 28, 2025

(54) DISPLAY DEVICE INCLUDING WINDOW AND METHOD FOR MANUFACTURING THE DISPLAY DEVICE

(71) Applicant: Samsung Display Co., Ltd., Yongin-si (KR)

(72) Inventors: SANGDUK LEE, Yongin-si (KR); HOIKWAN LEE, Yongin-si (KR); SUNGKOOK LEE, Yongin-si (KR); JUNGKYU LEE, Yongin-si (KR)

(21) Appl. No.: 18/929,797

(22) Filed: Oct. 29, 2024

(30) Foreign Application Priority Data
Feb. 27, 2024 (KR) 10-2024-0027724

(51) Int. Cl. H04M 1/02

(52) U.S. Cl. CPC H04M 1/0268; H04M 1/0216

(57) ABSTRACT

A display device includes: a display module including a folding area that is foldable based on a folding axis extending in a first direction, a first non-folding area, and a second non-folding area, wherein the first non-folding area and the second non-folding area are spaced apart from each other in a second direction crossing the first direction; a window disposed on the display module; and an optical layer disposed between the display module and the window. The window includes: a base substrate including a pattern part that overlaps the folding area and first and second flat parts that overlap the first and second non-folding areas, respectively; and a protection layer disposed on the base substrate. The pattern part includes a region recessed in a direction toward the base substrate from the protection layer.

This application claims priority to Korean Patent Application No. 10-2024-0027724, filed on Feb. 27, 2024, and all the benefits accruing therefrom under 35 U.S.C. § 119, the content of which in its entirety is herein incorporated by reference.

### BACKGROUND

The present disclosure herein relates to a window included in a display device and a method for manufacturing the display device.

Various display devices used for a television, a mobile phone, a tablet computer, and a game console are being developed. In recent years, flexible display devices including a slidable or foldable flexible display panel have been developed. The flexible display device may be folded, rolled, or bent unlike a rigid display device. The flexible display device, which is variously changeable in shape, may be carried regardless of a typical screen size, and thus user convenience may be improved. For a window included in the flexible display device, improved folding characteristics in a folding area of the window may be desired.

### SUMMARY

The present disclosure provides a display device including a window having improved folding characteristics in a folding area.

The present disclosure also provides a method for manufacturing a display device including a window manufactured with reduced costs.

An embodiment supported by the present disclosure provides a display device including: a display module having a folding area that is foldable based on a folding axis extending in a first direction, a first non-folding area, and a second non-folding area, wherein the first non-folding area and the second non-folding area are spaced apart from each other in a second direction crossing the first direction; a window disposed on the display module; and an optical layer disposed between the display module and the window. The window includes: a base substrate including a pattern part that overlaps the folding area, a first flat part that overlaps the first non-folding area, and a second flat part that overlaps the second non-folding area; and a protection layer disposed on the base substrate. The pattern part includes a recessed region recessed in a direction toward the base substrate from the protection layer.

In an embodiment, the base substrate may include a transparent resin.

In an embodiment, the pattern part may have a minimum thickness of about 10 μm to about 40 μm, and each of the first flat part and the second flat part may have a thickness of about 50 μm to about 100 μm.

In an embodiment, the base substrate may have a modulus of about 0.5 GPa to about 2 GPa.

In an embodiment, the display device may further include a first adhesive layer disposed between the protection layer and the base substrate, and the first adhesive layer may fill in the recessed region of the pattern part.

In an embodiment, the recessed region of the pattern part may be concave.

In an embodiment, the recessed region of the pattern part may have a cross-sectional shape including valleys and ridges connected to each other.

In an embodiment, the recessed region of the pattern part may include stepped portions that gradually descend in a direction toward a center of the pattern part from the first flat part and may include stepped portions that gradually descend in a direction toward the center of the recessed region from the second flat part.

In an embodiment, the display device may further include a second adhesive layer disposed between the protection layer and the base substrate.

In an embodiment, the base substrate may include a transparent film disposed on the second adhesive layer and a coating layer disposed on the transparent film.

In an embodiment, the transparent film may include one of polyethylene terephthalate (PET) or transparent polyimide (CPI), and the coating layer may include a transparent resin.

In an embodiment, the base substrate may include a thin-film glass substrate disposed on the second adhesive layer.

In an embodiment, the base substrate may include coating layer disposed on the thin-film glass substrate. In an embodiment, the base substrate may directly contact the optical layer.

In an embodiment, the display device may further include a lower film disposed below the display module, a support plate disposed below the lower film, and a lower plate disposed below the support plate.

In an embodiment, the lower plate may include holes that overlap the folding area and pass through the lower plate.

In an embodiment supported by the present disclosure, a method for manufacturing a display device includes: providing an optical layer to which an adhesive layer is attached; performing a laminating process including adhering a transparent film to the adhesive layer; and forming a coating layer including a pattern part having a concave shape by discharging an ink onto the transparent film. The ink includes a transparent resin, and the ink has viscosity of about 1000 cP to 2500 cP.

In an embodiment, the pattern part may have a minimum thickness of about 10 μm to about 40 μm.

In an embodiment supported by the present disclosure, a method for manufacturing a display device includes: forming a coating layer including a pattern part having a concave shape by discharging an ink onto a transparent film; and performing a laminating process including adhering the transparent film to an optical layer disposed below the transparent film through an adhesive layer. The ink includes a transparent resin, and the ink has viscosity of about 1000 cP to 2500 cP.

In an embodiment, the transparent film may include one of polyethylene terephthalate (PET) or transparent polyimide (CPI).

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

In the drawings:

FIG. 1A is a perspective view illustrating a display device according to an embodiment;

FIG. 1B is a perspective view illustrating the display device according to an embodiment;

FIG. 1C is a perspective view illustrating the display device according to an embodiment;

FIG. 1D is a perspective view illustrating the display device according to an embodiment;

FIG. 2A is a perspective view illustrating a display device according to an embodiment;

FIG. 2B is a perspective view illustrating the display device according to an embodiment;

FIG. 2C is a perspective view illustrating the display device according to an embodiment;

FIG. 3 is an exploded perspective view illustrating the display device according to an embodiment;

FIG. 4 is a cross-sectional view taken along line I-I′ of FIG. 3;

FIG. 5 is a plan view illustrating a display panel according to an embodiment;

FIGS. 6 to 11 are cross-sectional views illustrating the display device according to embodiments supported by the present disclosure;

FIGS. 12A and 12B are cross-sectional views illustrating a method for manufacturing a display device according to an embodiment supported by the present disclosure; and

FIGS. 13A and 13B are cross-sectional views illustrating a method for manufacturing a display device according to an embodiment supported by the present disclosure.

### DETAILED DESCRIPTION

In this specification, it will be understood that when one component (or region, layer, portion) is referred to as being ‘on’, ‘connected to’, or ‘coupled to’ another component, the component can be directly disposed/connected/coupled on/to the other component, or an intervening third component may also be present.

Like reference numerals refer to like elements throughout. In some aspects, in the figures, the thickness, ratio, and dimensions of components are exaggerated for clarity of illustration. The term “and/or” includes any and all combinations of one or more of the associated listed items.

It will be understood that although the terms such as, for example, ‘first’ and ‘second’ are used herein to describe various elements, these elements should not be limited by these terms. Terms are used to distinguish one component from other components. For example, a first element referred to as a first element in an embodiment can be referred to as a second element in another embodiment without departing from the scope of the appended claims. The terms of a singular form may include plural forms unless referred to the contrary.

Spatially relative terms, such as, for example, “below”, “lower”, “above”, and “upper”, may be used herein for ease of description to describe an element and/or a feature's relationship to another element(s) and/or feature(s) as illustrated in the drawings. The terms may be a relative concept and described based on directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as generally understood by those skilled in the art. Terms as defined in a commonly used dictionary should be construed as having the same meaning as in an associated technical context, and unless defined apparently in the description, the terms are not ideally or excessively construed as having formal meaning.

Hereinafter, embodiments of the inventive concept as supported by aspects of the present disclosure will be described with reference to the accompanying drawings.

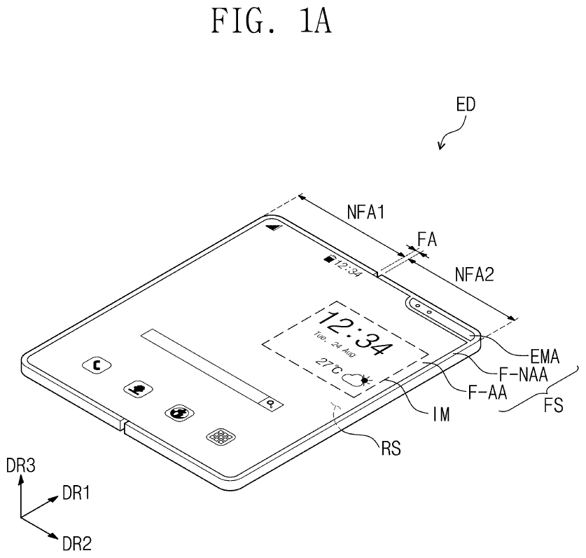

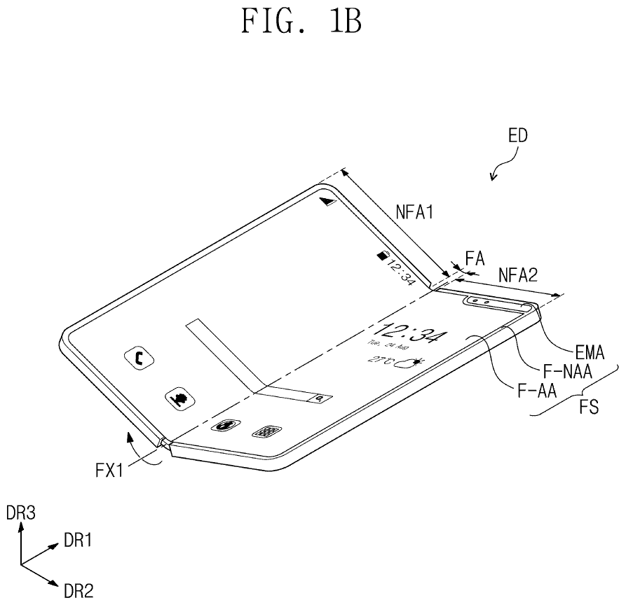

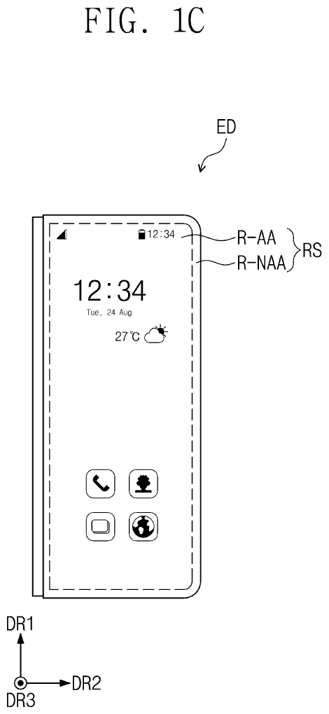

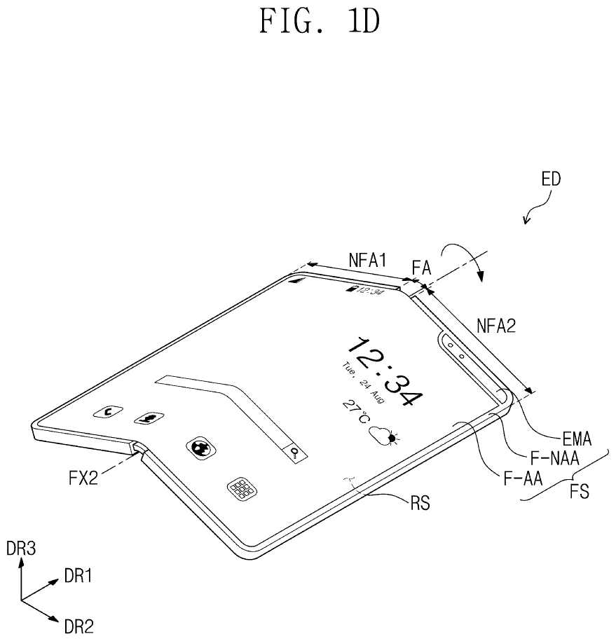

FIG. 1A is a perspective view illustrating a display device according to an embodiment. FIG. 1B is a perspective view illustrating the display device according to an embodiment. FIG. 1C is a perspective view illustrating the display device according to an embodiment. FIG. 1D is a perspective view illustrating the display device according to an embodiment.

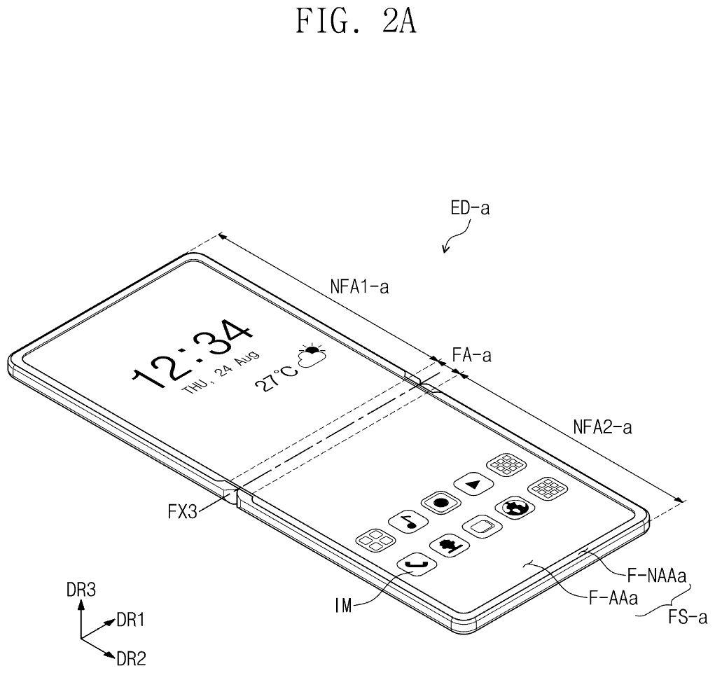

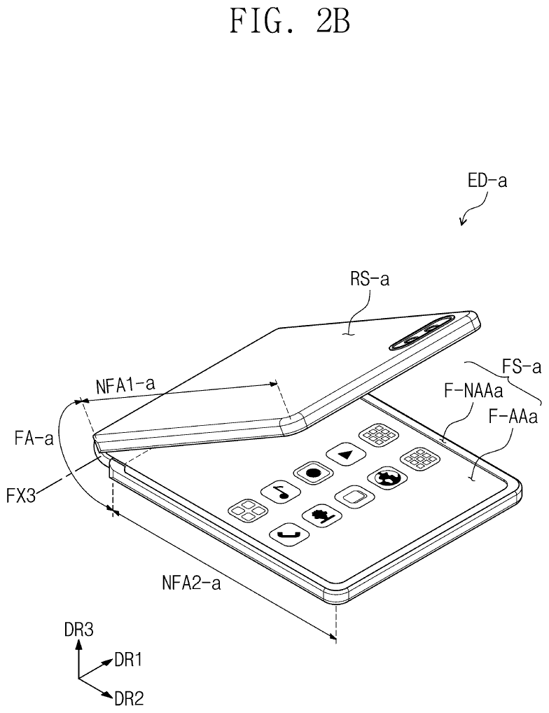

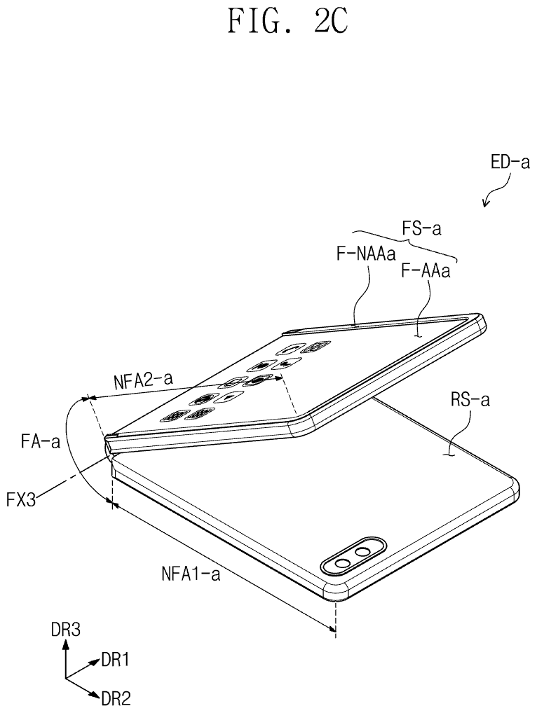

FIG. 1A is a perspective view illustrating an unfolded state of a display device ED according to an embodiment. The display device ED according to an embodiment may be activated by an electrical signal. Although the display device ED may be, e.g., a mobile phone, a tablet computer, a navigation unit for a vehicle, a game console, or a wearable device, embodiments of the present disclosure are not limited thereto. FIGS. 1A to 2C illustrate foldable display devices ED and ED-a as an example. Each of the foldable display devices ED and ED-a according to an embodiment may be a mobile phone.

The display device ED may include a first display surface FS defined by a first directional axis DR1 and a second directional axis DR2 crossing the first directional axis DR1. The display device ED may provide an image IM to a user through the first display surface FS. The display device ED may display the image IM in a direction of a third directional axis DR3 on the first display surface FS in parallel to each of the first directional axis DR1 and the second directional axis DR2.

In this specification, the first directional axis DR1 and the second directional axis DR2 may be perpendicular to each other, and the third directional axis DR3 is a normal direction with respect to the plane defined by the first and second directional axes DR1 and DR2. A thickness direction of the display device ED may be parallel to the third directional axis DR3. A front (or top) surface and a rear (or bottom) surface may be opposed to each other in the third directional axis DR3, and a normal direction of each of the front (or top) surface and the rear (or bottom) surface may be parallel to the third directional axis DR3. The front (or top) surface represents a surface adjacent to the first display surface FS, and the rear (or bottom) surface represents a surface spaced apart from the first display surface FS. In some aspects, the rear (bottom) surface represents a surface adjacent to a second display surface RS that will be described later. An upper side (or upper portion) represents a direction toward the first display surface FS, and a lower side (or lower portion) represents a direction away from the first display surface FS.

A cross-section of each of components represents a plane parallel to a third direction DR3 that is a thickness direction, and a plane represents to a surface perpendicular to the third direction DR3 that is the thickness direction. The plane represents a surface defined by the first directional axis DR1 and the second directional axis DR2.

In this specification, directions indicated by the first to third directional axes DR1, DR2, and DR3 may be relative concepts and converted with respect to each other. In some aspects, the directions indicated by the first to third directional axes DR1, DR2, and DR3 may be described as first to third directions and designated by the same reference numerals.

The display device ED may sense an external input applied from the outside. The external input may include various types of inputs provided from the outside of the display device ED. For example, the external input may include a contact generated by a portion of a user's body such as, for example, hands of the user and an external input (e.g., hovering) that is applied by being adjacent to the display device ED or being disposed adjacent by a predetermined distance thereto. In some aspects, the external input may be of various types such as, for example, force, pressure, temperature, and light.

The display device ED may include the first display surface FS and the second display surface RS. The first display surface FS may include a first active area F-AA, a first peripheral area F-NAA, and an electronic module area EMA. The second display surface RS may be defined as a surface opposing at least a portion of the first display surface FS. That is, the second display surface RS may be defined as a portion of a rear surface of the display device ED.

The first active area F-AA may be activated by an electrical signal. The first active area F-AA may be an area on which the image IM is displayed and which senses an external input.

The first peripheral area F-NAA may be an area on which the image IM is not displayed. The first peripheral area F-NAA may be disposed adjacent to the active area F-AA. The first peripheral area F-NAA may have a predetermined color. The first peripheral area F-NAA may surround the first active area F-AA. Thus, the first active area F-AA may substantially have a shape defined by the first peripheral area F-NAA. However, this is merely illustrative. For example, the first peripheral area F-NAA may be disposed adjacent to a single side of the first active area F-AA or omitted.

Various electronic modules may be disposed on the electronic module area EMA. For example, the electronic module may include at least one of a camera, a speaker, an optical detection sensor, and a thermal detection sensor. The electronic module area EMA may sense an external subject received through the display surfaces FS and RS or provide a sound signal such as, for example, a voice to the outside through the display surfaces FS and RS. The electronic module may include a plurality of components. However, embodiments supported by the present disclosure are not limited to the components of the electronic module.

The electronic module area EMA may be surrounded by the first peripheral area F-NAA. However, this is merely illustrative, and embodiments supported by the present disclosure are not limited to the electronic module area EMA. For example, the electronic module area EMA may be surrounded by the first active area F-AA and the first peripheral area F-NAA, and the electronic module area EMA may be disposed in the first active area F-AA.

The display device ED according to an embodiment may include at least one folding area FA and a plurality of non-folding areas NFA1 and NFA2 each extending from the folding area FA. For example, a first non-folding area NFA1, the folding area FA, and a second non-folding area NFA2 may be sequentially defined in the second direction DR2. The display device ED may be divided into the first non-folding area NFA1 and the second non-folding area NFA2, which are spaced apart from each other with the folding area FA between the first non-folding area NFA1 and the second non-folding area NFA2 in the second direction DR2. For example, the first non-folding area NFA1 may be disposed at one side of the folding area FA in the second direction DR2, and the second non-folding area NFA2 may be disposed at the other side of the folding area FA in the second direction DR2.

Although an embodiment of the display device ED including one folding area FA is illustrated in FIG. 1A, embodiments of the present disclosure are not limited thereto. For example, a plurality of folding areas may be defined on the display device ED. For example, the display device according to an embodiment may include two or more folding areas and three or more non-folding areas disposed between the folding areas.

FIG. 1B is a perspective view illustrating a folding operation of the display device ED according to an embodiment. FIG. 1C is a perspective view illustrating a folded state of the display device ED according to an embodiment. FIG. 1D is a perspective view illustrating a folding operation of the display device ED according to an embodiment.

Referring to FIG. 1B, the display device ED according to an embodiment may be folded based on a first folding axis FX1 extending in the first direction DR1. The folding area FA may have a predetermined curvature and a predetermined radius of curvature in the folded state of the display device ED. The display device ED may be folded based on the first folding axis FX1 and deformed into an in-folding state such that the first non-folding area NFA1 and the second non-folding area NFA2 face each other and the first display surface FS is not exposed to the outside.

Referring to FIG. 1C, the second display surface RS may be recognized by the user in a state in which the display device ED according to an embodiment is in-folded. Here, the second display surface RS may include a second active area R-AA. The second active area R-AA may be activated by an electrical signal. The second active area F-AA may be an area on which the image IM is displayed and which senses various types of external inputs.

In some aspects, the second display surface RS may include a second peripheral area R-NAA. The second peripheral area R-NAA may be disposed adjacent to the second active area R-AA. The second peripheral area R-NAA may have a predetermined color. The second peripheral area F-NAA may surround the second active area R-AA. Although not illustrated, the display device ED may further include an electronic module area in which electronic modules including various components are disposed on the second display surface RS. However, embodiments of the present disclosure are not limited thereto.

According to an embodiment, in the in-folding state of the display device ED, a distance between the first non-folding area NFA1 and the second non-folding area NFA2 may be less than a radius of a circle defined by a radius of curvature of the folding area FA. Here, the folding area FA may be folded into a dumbbell shape, and the distance between the first non-folding area NFA1 and the second non-folding area NFA2 may decrease. Thus, the display device ED that is slimmer in the folded state may be provided.

Referring to FIG. 1D, the display device ED according to an embodiment may be folded based on a second folding axis FX2 extending in the first direction DR1. The display device ED may be folded based on the second folding axis FX2 and deformed into an out-folding state such that the first display surface FS is exposed to the outside. In an embodiment, the display device ED may alternately perform an in-folding operation and an out-folding operation from an unfolding operation in a repeated manner. However, embodiments of the present disclosure are not limited thereto.

Although the display device ED is folded based on one folding axis FX1 or FX2 as an example in FIGS. 1A to 1D, embodiments supported by the present disclosure are not limited to the number of folding axes and the number of non-folding areas corresponding thereto. For example, the display device ED may be folded based on the plurality of folding axes, such that the first display surface FS and the second display surface RS partially face each other. Although the first and second folding axes FX1 and FX2 are parallel to a long side of the display device ED in the drawings, embodiments of the present disclosure are not limited thereto. For example, the first and second folding axes FX1 and FX2 may be parallel to a short side of the display device ED.

In the display device ED, the first non-folding area NFA1 and the second non-folding area NFA2 may be defined as an area having the display surface FS or RS parallel to the plane defined by the first directional axis DR1 and the second directional axis DR2 in the folded state as illustrated in FIG. 1C, and the folding area FA may be an area between the first non-folding area NFA1 and the second non-folding area NFA2. The folding area FA may include a curved portion that is bent to have a predetermined curvature in the folded state.

FIG. 2A is a perspective view illustrating a display device according to an embodiment. FIG. 2B is a perspective view illustrating the display device according to an embodiment. FIG. 2C is a perspective view illustrating the display device according to an embodiment.

FIGS. 2A to 2C are perspective views illustrating a display device ED-a according to another embodiment supported by the present disclosure. FIG. 2A is a perspective view illustrating an unfolded state of the display device ED-a. FIGS. 2B and 2C are is perspective views illustrating folding operations of the display device ED-a. FIG. 2B is a perspective view illustrating an in-folding operation of the display device ED-a illustrated in FIG. 2A. FIG. 2C is a perspective view illustrating an out-folding operation of the display device ED-a illustrated in FIG. 2A. FIG. 2A is a view illustrating the display device ED-a in a second mode.

Referring to FIG. 2A, the display device ED-a may be folded based on a third folding axis FX3 extending in the first direction DR1. An extension direction of the third folding axis FX3 may be parallel to an extension direction of a short side of the display device ED-a.

The display device ED-a may be divided into a folding area FA-a, a first non-folding area NFA1-a adjacent to one side of the folding area FA-a, and a second non-folding area NFA2-a adjacent to the other side of the folding area FA-a. The first non-folding area NFA1-a and the second non-folding area NFA2-a may be spaced apart from each other with the folding area FA-a between the first non-folding area NFA1-a and the second non-folding area NFA2-a.

The folding area FA-a may be an area folded based on the third folding axis FX3. In a folded state of the display device ED-a, the folding area FA-a may have a predetermined curvature and a predetermined radius of curvature. The display device ED-a may be in-folded such that the first non-folding area NFA1-a and the second non-folding area NFA2-a may face each other, and a display surface FS-a is not exposed to the outside.

Referring to FIG. 2A, in a spread state (i.e., an unfolded state) of the display device ED-a according to an embodiment, the display surface FS-a may be recognized by a user. As described with reference to FIGS. 1A to 1D, the display surface FS-a of the display device ED-a may include an active area F-AAa and a peripheral area F-NAAa. The active area F-AAa may be an area on which an image IM is displayed and which senses various types of external inputs.

Referring to FIG. 2B, in an in-folded state of the display device ED-a according to an embodiment, a rear surface RS-a may be recognized by the user. For example, the rear surface RS-a may function as a second display surface on which a video or an image is displayed. In some aspects, an electronic module area on which an electronic module including various components is disposed may be disposed even on the rear surface RS-a. According to an embodiment, the rear surface RS-a of the display device ED-a may further include an active area on which an image is displayed.

Referring to FIG. 2C, the display device ED-a may be folded based on the third folding axis FX3 and deformed into an out-folding state in which one area of the rear surface Rs-a, which overlaps the first non-folding area NFA1-a faces the other area, which overlaps the second non-folding area NFA2-a.

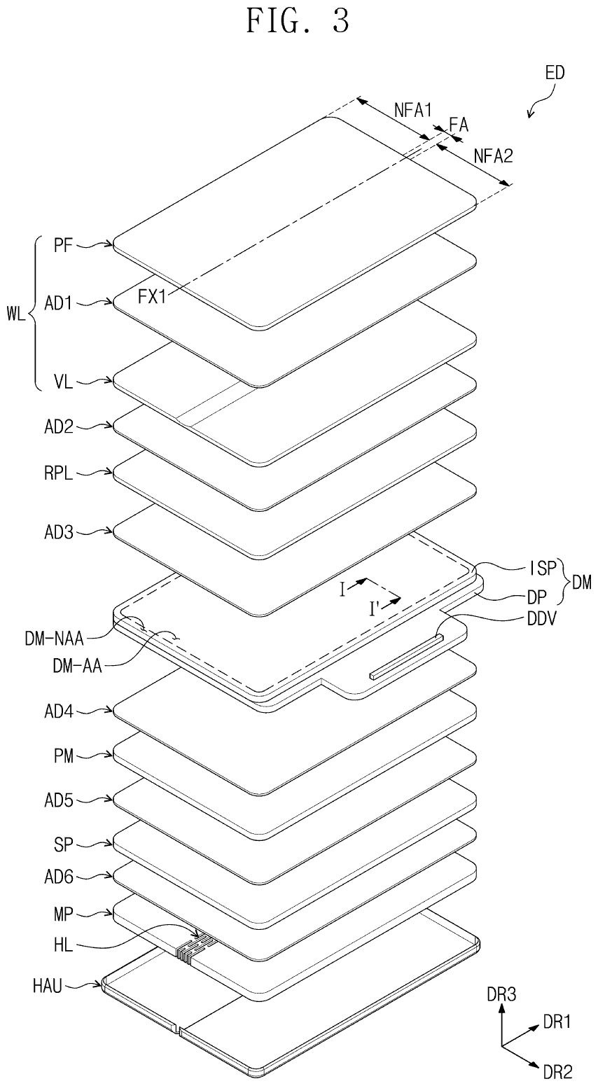

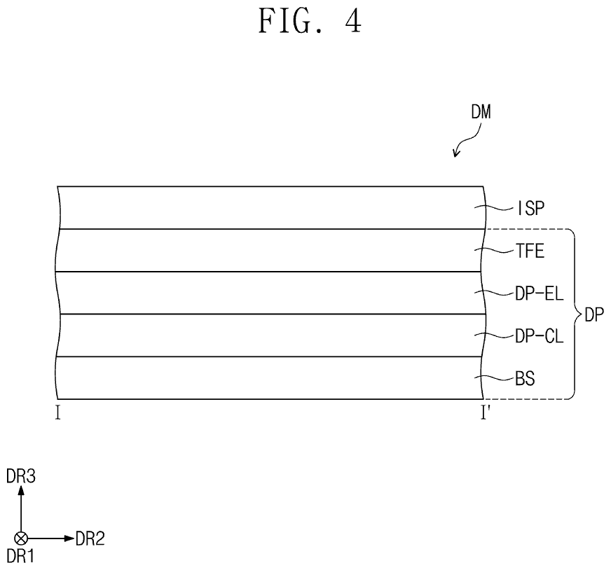

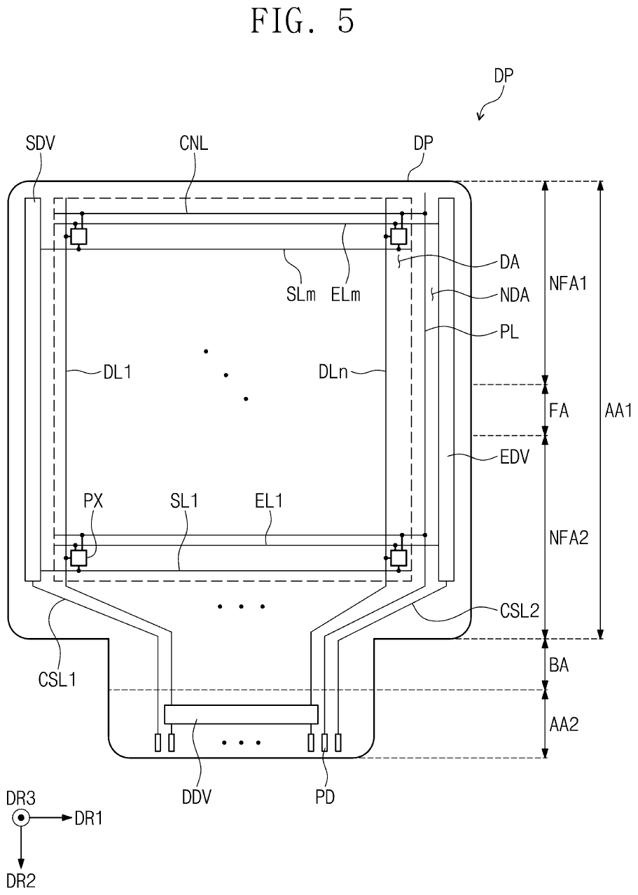

FIG. 3 is an exploded perspective view illustrating the display device according to an embodiment. FIG. 4 is a cross-sectional view taken along line I-I′ of FIG. 3. FIG. 5 is a plan view illustrating a display panel according to an embodiment. Hereinafter, features to be described in the display device ED may be applied to the display device ED-a described in FIGS. 2A to 2C.

Referring to FIG. 3, the display device ED may include a window WL, a display module DM, an optical layer RPL, a display module DM, a lower film PM, a support plate SP, a lower plate MP, and a housing HAU.

The housing HAU may be coupled with the window WL to define an appearance of the display device ED. The housing HAU may include a material having relatively high rigidity. For example, the housing HAU may include a plurality of frames and/or support plates, which are formed of glass, plastic, or metal. The housing HAU may provide a predetermined accommodation space. The display module DM may be accommodated in the accommodation space and protected from an external impact. According to an embodiment, the housing HAU that overlaps the folding area FA may further include a hinge structure for guiding the folding operation of the display device ED.

The display module DM may be disposed below the optical layer RPL. The display module DM may be activated by an electric signal. As the display module DM is activated, the image IM (refer to FIG. 1A) may be displayed on the active area F-AA (refer to FIG. 1A) of the display device ED. A display area DM-AA and a non-display area DM-NAA may be defined on the display module DM. The display area DM-AA may be activated by an electrical signal. The non-display area DM-NAA may be disposed adjacent to at least one side of the active area DM-AA. A circuit or a line for driving the display area DM-AA may be disposed on the non-display area DM-NAA.

The optical layer RPL may be disposed between the display module DM and the window WL. The optical layer RPL may be an anti-reflection layer that reduces a reflectance of external light incident from the outside of the display module DM. The optical layer RPL may be disposed on the display module DM through a continuous process. The optical layer RPL may include a polarizing plate or a color filter layer. For example, the optical layer RPL may include at least one of a phase retarder, a polarizer, a polarizing film, and a polarizing filter. Alternatively, the optical layer RPL may include a plurality of color filters arranged in a predetermined arrangement and a black matrix disposed adjacent to the color filters.

The image IM (refer to FIG. 1A) generated in the display module DM may be provided to the user through the window WL. The window WL may include a polymer substrate or a glass substrate.

The window WL according to an embodiment may include a protection layer PF and a base substrate VL. Each of the protection layer PF and the base substrate VL may include an optically clear insulating material.

The protection layer PF may be disposed on the base substrate VL. The protection layer PF may be a functional layer that protects a top surface of the base substrate VL. The protection layer PF may include a polymer film. The protection layer PF may include an anti-fingerprint coating agent, a hard coating agent, and an anti-static agent.

The lower film PM may protect a lower portion of the display panel DP. The lower film PM may include a flexible plastic material. For example, the lower film PM may include polyethylene terephthalate.

The support plate SP may be disposed below the display panel DP. One portion of the support plate SP according to an embodiment supported by the present disclosure may be bent to absorb an impact applied between components disposed on the support plate SP and the housing HAU. In some aspects, the support plate SP may prevent foreign substances from being introduced into the components disposed on the support plate SP.

The lower plate MP may be disposed below the support plate SP. The lower plate MP may include a plurality of holes HL that overlap the folding area and pass through the lower plate MP to allow the folding operation of the display device ED to be easily performed. The lower plate MP may include metal. For example, the lower plate MP may include at least one of aluminum (Al) and molybdenum (Mo). However, embodiments of the present disclosure are not limited thereto. For example, the lower plate MP may include a matrix including a filler and woven fiber lines disposed in the matrix. The fiber lines may be arranged in a fabric shape in the matrix.

The fiber lines may include a reinforced fiber composite. The reinforced fiber composite may be one of carbon fiber-reinforced plastics (CFRP) or glass fiber-reinforced plastic (GFRP). One strand of fiber included in one fiber line may have a diameter of 3 μm or more and 10 μm or less.

The matrix according to an embodiment may include at least one of epoxy, polyester, polyamides, polycarbonates, polypropylene, polybutylene, and vinyl ester.

The matrix may include a filler. The filler may include at least one of barium sulphate, sintered talc, barium titanate, titanium oxide, clay, alumina, mica, boehmite, zinc borate, and zinc stannate.

The display device ED according to an embodiment may further include at least one of a cushion layer and a shielding layer. The cushion layer may prevent a pressed phenomenon and plastic deformation of the lower plate MP caused by an external impact and force. The cushion layer may include an elastomer such as, for example, a sponge, a foam, or a urethane resin. In some aspects, the cushion layer may include at least one of an acrylic-based polymer, an urethane-based polymer, a silicon-based polymer, and an imide-based polymer. The shielding layer may be an electromagnetic wave shielding layer or a heat dissipation layer.

The display device ED according to an embodiment may further include first to sixth adhesive layers AL1 to AD6. The first adhesive layer AD1 may be disposed between the base substrate VL and the protection layer PF. The second adhesive layer AD2 may be disposed between the optical layer RPL and the base substrate VL. The third adhesive layer AD3 may be disposed between the display module DM and the optical layer RPL. The fourth adhesive layer AD4 may be disposed between the lower film PM and the display module DM. The fifth adhesive layer AD5 may be disposed between the support plate SP and the lower film PM. The sixth adhesive layer AD6 may be disposed between the lower plate MP and the support plate SP.

Each of the first to sixth adhesive layers AD1 to AD6 and adhesive layers that will be described later may include a typical adhesive such as, for example, a pressure-sensitive adhesive (PSA), an optically clear adhesive (OCA), and an optically clear resin (OCR). However, embodiments of the present disclosure are not limited thereto. At least one of the first to sixth adhesive layers AL1 to AD6 may be omitted from the display device ED according to an embodiment.

Referring to FIG. 4, the display module DM may include a display panel DP and an input sensing layer ISP disposed on the display panel DP. The display panel DP may be a component that substantially generates an image. The display panel DP may be a light emitting display panel. For example, the display panel DP may be an organic light emitting display panel, an inorganic light emitting display panel, a micro-LED display panel, a micro-OLED display panel, or a nano-LED display panel.

The display panel DP may include a base layer BS, a circuit layer DP-CL, a display element layer DP-EL, and an encapsulation layer TFE, which are sequentially laminated with each other. Unlike as illustrated, a functional layer may be further disposed between two adjacent layers of the base layer BS, the circuit layer DP-CL, the display element layer DP-EL, and the encapsulation layer TFE.

The base layer BS may provide a base surface on which the circuit layer DP-CL is disposed. The base layer BS may be a flexible board that is bendable, foldable, or rollable. The base layer BS may include a glass substrate, a metal substrate, or a polymer substrate. However, embodiments of the present disclosure are not limited thereto. For example, the base layer BS may be an inorganic layer, an organic layer, or a composite layer.

The base layer BS may include a single layer or multiple layers. For example, the base layer BS may include a first synthetic resin layer, a single layered or multiple layered inorganic layer, and a second synthetic resin layer disposed on the single layered or multiple layered inorganic layer. Each of the first and second synthetic resin layers may include a polyimide-based resin. In some aspects, each of the first and second synthetic resin layers may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin and a perylene-based resin. In this specification, a term “˜based” resin represents a feature of including a functional group of “˜˜”.

The circuit layer DP-CL may be disposed on the base layer BS. The circuit layer DP-CL may include an insulation layer, a semiconductor pattern, a conductive pattern and a signal line. The display element layer DP-EL may be disposed on the circuit layer DP-CL. The display element layer DP-EL may include a light emitting element (not illustrated). For example, the light emitting element may include an organic light emitting material, an inorganic light emitting material, an organic-inorganic light emitting material, a quantum dot, a quantum rod, a micro-LED, or a nano-LED.

The encapsulation layer TFE may be disposed on the display element layer DP-EL. The encapsulation layer TFE may protect the display element layer DP-EL from moisture, oxygen, and foreign substances such as, for example, dust particles. The encapsulation layer TFE may include at least one inorganic layer. For example, the encapsulation layer TFE may include an inorganic layer, an organic layer, and an inorganic layer, which are sequentially laminated with each other.

The input sensing layer ISP may be disposed on the display panel DP. The input sensing layer ISP may be disposed directly on the encapsulation layer TFE. Alternatively, an adhesive member may be disposed between the input sensing layer ISP and the display panel DP.

In this specification, the feature in which one component is disposed directly on another component represents that a third component is not disposed between one component and another component. That is, the feature in which one component is “disposed directly” on another component represents that one component “contacts” another component.

The input sensing part ISP may sense an external input, convert the external input into an input signal, and provide the input signal to the display panel DP. For example, the input sensing layer ISP may be a touch sensing layer that senses a touch. The input sensing layer ISP may recognize a user's direct touch, a user's indirect touch, an object's direct touch, or an object's indirect touch.

The input sensing layer ISP may sense at least one of a position and intensity (pressure) of a touch applied from the outside. The input sensing layer ISP may have various structures or be formed of various materials. However, embodiments of the present disclosure are not limited thereto. For example, the input sensing layer ISP may sense an external input in a capacitive manner. The display panel DP may receive an input signal from the input sensing layer ISP and generate an image corresponding to the input signal.

Referring to FIG. 5, the display panel DP may include pixels PX, a scan driver SDV, a data driver DDV, and an emission driver EDV.

The display panel DP may include a first area AA1, a second area AA2, and a bending area BA disposed between the first area AA1 and the second area AA2. The bending area BA may extend in the first direction DR1, and the first area AA1, the bending area BA, and the second area AA2 may be arranged in the second direction DR2. The bending area BA may be bent such that the second area AA2 overlaps a bottom surface of the first area AA1 along a bending axis extending in the first direction DR1. According to an embodiment, a width of each of the bending area BA and the second area AA2 in the first direction DR1 may be less than a width of the first area AA1 in the first direction DR1. Thus, the bending area BA may be easily bent toward a bottom surface of the first area AA1.

The first area AA1 may include a display area DA and a non-display area NDA disposed around the display area DA. The non-display area NDA may surround the display area DA. The display area DA may display an image, and the non-display area NDA may not display an image. Each of the second area AA2 and the bending area BA may not display an image.

The first area AA1 may include a first non-folding area NFA1, a second non-folding area NFA2, and a folding area FA disposed between the first non-folding area NFA1 and the second non-folding area NFA2, which are arranged in the second direction DR2. The first and second non-folding areas NFA1 and NFA2 and the folding area FA may correspond to the first and second non-folding areas NFA1 and NFA2 and the folding area FA of the display device ED illustrated in FIG. 1A.

The first area AA1 may be bent and folded based on the above-described folding axes. For example, as the folding area FA of the first area AA1 is folded based on the above-described folding axes, the display panel DP may be folded.

The display panel DP may include a plurality of pixels PX, a plurality of scan lines SL1 to SLm, a plurality of data lines DL1 to DLn, a plurality of emission lines EL1 to Elm, first and second control lines CSL1 and CSL2, a power line PL, a plurality of connection lines CNL, and a plurality of pads PD. Here, m and n are natural numbers. The pixels PX may be disposed on the display area DA and connected to the scan lines SL1 to SLm, the data lines DL1 to DLn, and the emission lines EL1 to ELm.

The scan driver SDV and the emission driver EDV may be disposed on the non-display area NDA. Each of the scan driver SDV and the emission driver EDV may be disposed on the non-display areas NDA respectively disposed adjacent to both sides, which are opposite to each other in the second direction DR2, of the first area AA1. The data driver DDV may be disposed on the second area AA2. The data driver DDV may be manufactured in the form of an integrated circuit chip and mounted on the second area AA2.

The scan lines SL1 to SLm may each extend in the second direction DR2 and be connected to the scan driver SDV. The data lines DL1 to DLn may each extend in the first direction DR1 and be connected to the data driver DDV through the bending area BA. The data driver DDV may be connected to the pixels PX through the data lines DL1 to DLn. The emission lines EL1 to Elm may each extend in the second direction DR2 and be connected to the emission driver EDV.

The power line PL may extend in the first direction DR1 and be disposed on the non-display area NDA. The power line PL may be disposed between the display area DA and the emission driver EDV. The power line PL may extend to the second area AA2 through the bending area BA. In a plan view, the power line PL may extend toward a lower end of the second area AA2. The power line PL may receive a driving voltage.

The connection lines CNL may each extend in the second direction DR2 and be arranged in the first direction DR1. The connection lines CNL may be connected to the power line PL and the pixels PX. The driving voltage may be applied to the pixels PX through the power line PL and the connection lines CNL, which are connected to each other.

The first control line CSL1 may be connected to the scan driver SDV and extend toward a lower end of the second area AA2 through the bending area BA. The second control line CSL2 may be connected to the emission driver EDV and extend toward the lower end of the second area AA2 through the bending area BA. The data driver DDV may be disposed between the first control line CSL1 and the second control line CSL2.

In a plan view, the pads PD may be disposed adjacent to the lower end of the second area AA2. The data driver DDV, the power line PL, the first control line CSL1, and the second control line CSL2 may be connected to the pads PD.

The data lines DL1 to DLn may be connected to the corresponding pads PD through the data driver DDV. For example, the data lines DL1 to DLn may be connected to the data driver DDV, and the data driver DDV may be connected to the pads PD that correspond to the data lines DL1 to DLn, respectively.

Although not illustrated, a printed circuit board may be connected to the pads PD, and a timing controller and a voltage generator may be disposed on the printed circuit board. The timing controller may be manufactured in a form of an integrated circuit chip and mounted to the printed circuit board. The timing controller and the voltage generator may be connected to the pads PD through the printed circuit board.

The timing controller may control an operation of each of the scan driver SDV, the data driver DDV, and the emission driver EDV. The timing controller may generate a scan control signal, a data control signal, and an emission control signal in response to control signals received from the outside. The voltage generator may generate a driving voltage.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside and convert a data format of the image signals to match with interface specifications of the data driver DDV, thereby providing the converted image signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DL1 to DLn. The emission driver EDV may generate a plurality of emission signals in response to the emission control signal. The emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals. The pixels PX may have an emission time that is controlled by the emission signals. Each of the pixels PX may include transistors, a capacitor, and a light emitting element connected thereto. Each of the transistors may include a semiconductor pattern. The semiconductor pattern may include polysilicon, amorphous silicon, or a metal oxide. The semiconductor pattern may be doped with an n-type dopant or a p-type dopant. The semiconductor pattern may include a highly doped area and a lightly doped area. The highly doped area may have a conductivity greater than the conductivity of the lightly doped area and substantially serve as a source electrode and a drain electrode of the transistor TR. The lightly doped area may substantially correspond to an active (or channel) of the transistor.

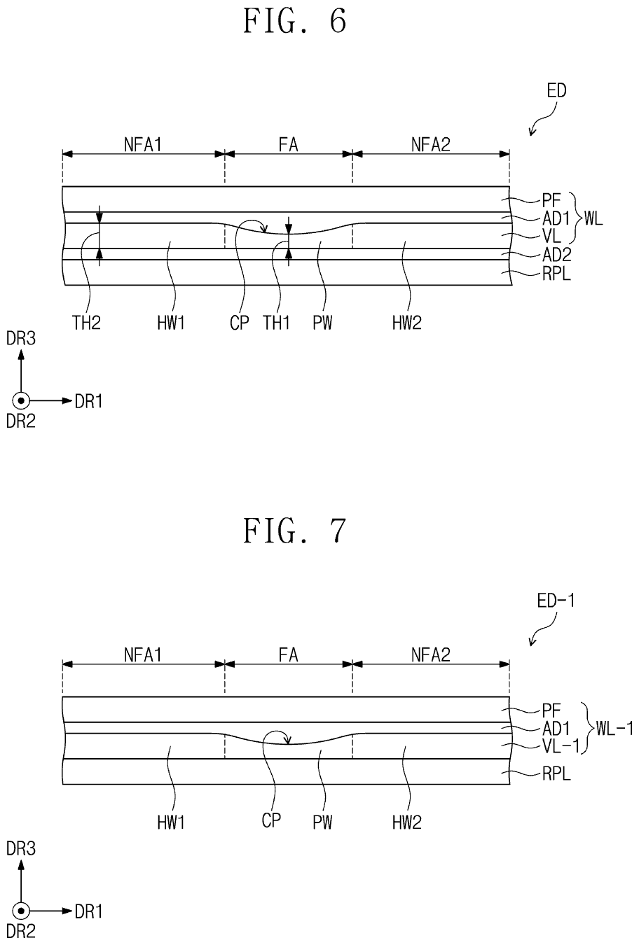

FIGS. 6 to 11 are cross-sectional views illustrating the display device according to embodiments supported by the present disclosure. FIGS. 6 to 11 illustrate the window and the optical layer RPL disposed below the window among the components included in the display device, and the other components described in FIG. 3 are omitted. In some aspects, the window described in FIGS. 6 to 11 may be applied to the display devices ED and ED-a in FIGS. 1A to 2C.

Referring to FIG. 6, the display device ED according to an embodiment may include the window WL and the optical layer RPL disposed below the window WL. The window WL and the optical layer RPL may be bonded to each other by the second adhesive layer AD2.

The window WL according to an embodiment may include the protection layer PF and the base substrate VL. The protection layer PF and the base substrate VL may be bonded to each other by the first adhesive layer AD1. According to an embodiment, the top surface of the base substrate VL may contact the first adhesive layer AD1, and a bottom surface of the base substrate VL may contact the second adhesive layer AD2.

The base substrate VL may include a first flat part HW1 overlapping the first non-folding area NFA1, a second flat part HW2 overlapping the second non-folding area NFA2, and a pattern part PW overlapping the folding area FA.

The pattern part PW may include a recessed region CP recessed in a direction toward the base substrate VL in the protection layer PF. According to the embodiment, the recessed region CP may have a concave shape in a cross-section in the first direction DR1. The first adhesive layer AD1 may fill in the recessed region CP.

According to an embodiment supported by the present disclosure, the base substrate VL may be formed of a transparent resin. The transparent resin used to make the base substrate VL may be a high-viscosity resin. The resin used to make the base substrate VL may have viscosity of 1000 cP to 2500 cP. The base substrate VL may have a modulus of 0.5 GPa to 2 GPa and a crack strain of 2% to 15%.

According to an embodiment supported by the present disclosure, a minimum thickness TH1 of the pattern part PW may be 10 μm to 40 μm. A second thickness TH2 of each of the first flat part HW1 and the second flat part HW2 may be 50 μm to 100 μm.

According to an embodiment supported by the present disclosure, as the base substrate VL of the window WL includes the transparent resin, manufacturing costs for the window WL may be reduced. In some aspects, the varied thickness of the pattern part PW overlapping the folding area FA may prevent cracks from occurring in the base substrate VL during the folding operation of the display device ED. Thus, the display device ED having an improved folding characteristic may be provided.

Referring to FIG. 7, a display device ED-1 according to an embodiment may include a window WL-1 and an optical layer RPL disposed below the window WL-1.

The window WL-1 according to an embodiment may include a protection layer PF and a base substrate VL-1. The protection layer PF and the base substrate VL-1 may be bonded to each other by a first adhesive layer AD1. A top surface of the base substrate VL-1 may contact the first adhesive layer AD1.

The base substrate VL-1 may include a first flat part HW1 overlapping the first non-folding area NFA1, a second flat part HW2 overlapping the second non-folding area NFA2, and a pattern part PW overlapping the folding area FA.

The pattern part PW may include a recessed region CP recessed in a direction toward the base substrate VL-1 in the protection layer PF. According to the embodiment, the recessed region CP may have a concave shape in a cross-section in the first direction DR1. The first adhesive layer AD1 may fill in the recessed region CP.

A bottom surface of the base substrate VL-1 may be disposed directly on the protection layer PF. That is, the bottom surface of the base substrate VL-1 may contact the protection layer PF. According to the embodiment, the base substrate VL-1 may be provided by directly applying a transparent resin onto the protection layer PF through an inkjet process or dispensing coating process.

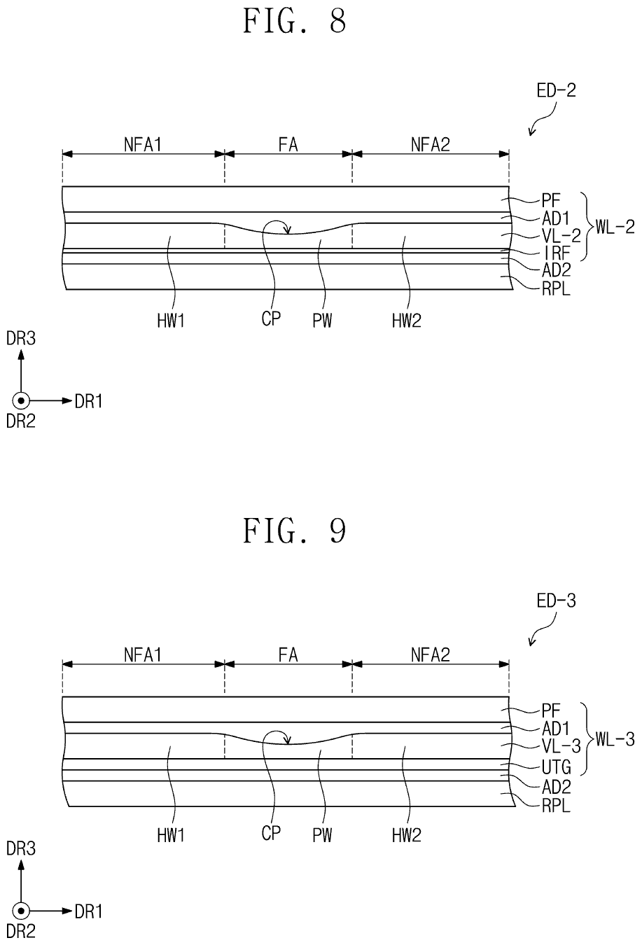

Referring to FIG. 8, a display device ED-2 according to an embodiment may include a window WL-2 and an optical layer RPL disposed below the window WL-2.

The window WL-2 according to an embodiment may include a transparent film IRF and a coating layer VL-2 disposed on the transparent film IRF. The coating layer VL-2 may be provided by directly applying a transparent resin onto the transparent film IRF through an inkjet process or a dispensing coating process. The transparent film IRF may include one of polyethylene terephthalate (PET) or transparent polyimide (CPI). The coating layer VL-2 may be bonded to a protection layer PF by a first adhesive layer AD1. A top surface of the coating layer VL-2 may contact the first adhesive layer AD1.

The coating layer VL-2 may include a first flat part HW1 overlapping the first non-folding area NFA1, a second flat part HW2 overlapping the second non-folding area NFA2, and a pattern part PW overlapping the folding area FA.

The pattern part PW may include a recessed region CP recessed in a direction toward the transparent film IRF in the protection layer PF. According to an embodiment, the recessed region CP may have a concave shape in a cross-section in the first direction DR1. The first adhesive layer AD1 may fill in the recessed region CP.

According to an embodiment, the transparent film IRF and the optical layer RPL may be bonded to each other by a second adhesive layer AD2.

Referring to FIG. 9, a display device ED-3 according to an embodiment may include a window WL-3 and an optical layer RPL disposed below the window WL-3.

The window WL-3 according to an embodiment may include a thin-film glass substrate UTG and a coating layer VL-3 disposed on the thin-film glass substrate UTG. The coating layer VL-3 may be provided by directly applying a transparent resin onto the thin-film glass substrate UTG through an inkjet process or a dispensing coating process. The thin-film glass substrate UTG may be chemical reinforced glass. The thin-film glass substrate UTG according to an embodiment may have a thickness of 15 μm to 45 μm.

The coating layer VL-3 may be bonded to a protection layer PF by a first adhesive layer AD1. A top surface of the coating layer VL-3 may contact the first adhesive layer AD1.

The coating layer VL-3 may include a first flat part HW1 overlapping the first non-folding area NFA1, a second flat part HW2 overlapping the second non-folding area NFA2, and a pattern part PW overlapping the folding area FA.

The pattern part PW may include a recessed region CP recessed in a direction toward the thin-film glass substrate UTG in the protection layer PF. According to an embodiment, the recessed region CP may have a concave shape in a cross-section in the first direction DR1. The first adhesive layer AD1 may fill in the recessed region CP.

According to an embodiment, the thin-film glass substrate UTG and the optical layer RPL may be bonded to each other by a second adhesive layer AD2.

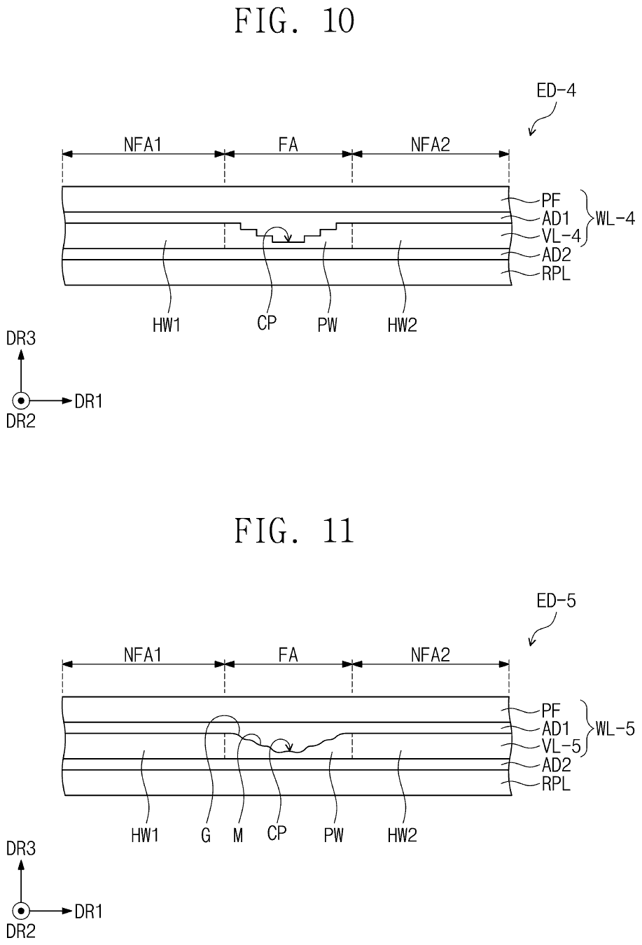

Referring to FIG. 10, a display device ED-4 according to an embodiment may include a window WL-4 and an optical layer RPL disposed below the window WL-4. The window WL-4 and the optical layer RPL may be bonded to each other by a second adhesive layer AD2.

The window WL-4 according to an embodiment may include a protection layer PF and a base substrate VL-4. The protection layer PF and the base substrate VL-4 may be bonded to each other by a first adhesive layer AD1. According to an embodiment, a top surface of the base substrate VL-4 may contact the first adhesive layer AD1, and a bottom surface of the base substrate VL-4 may contact the second adhesive layer AD2. The base substrate VL-4 may include a transparent resin.

The base substrate VL-4 may include a first flat part HW1 overlapping the first non-folding area NFA1, a second flat part HW2 overlapping the second non-folding area NFA2, and a pattern part PW overlapping the folding area FA.

The pattern part PW may include a recessed region CP recessed in a direction toward the base substrate VL in the protection layer PF. According to an embodiment, the recessed region CP may have stepped portions (i.e., have a shape of stairs) that gradually descend in a direction toward a center of the recessed region CP in a cross-section in the first direction DR1. That is, the recessed region CP may have stepped portions (i.e., have a shape of stairs) that gradually descend in a direction toward the center of the recessed region CP from the first flat part HW1 and stepped portions (i.e. have a shape of stairs) that gradually descend toward the center of the recessed region CP from the second flat part HW2.

Referring to FIG. 11, a display device ED-5 according to an embodiment may include a window WL-5 and an optical layer RPL disposed below the window WL-5. The window WL-5 and the optical layer RPL may be bonded to each other by a second adhesive layer AD2.

The window WL-5 according to an embodiment may include a protection layer PF and a base substrate VL-5. The protection layer PF and the base substrate VL-5 may be bonded to each other by a first adhesive layer AD1. According to an embodiment, a top surface of the base substrate VL-5 may contact the first adhesive layer AD1, and a bottom surface of the base substrate VL-5 may contact the second adhesive layer AD2. The base substrate VL-5 may include a transparent resin.

The base substrate VL-5 may include a first flat part HW1 overlapping the first non-folding area NFA1, a second flat part HW2 overlapping the second non-folding area NFA2, and a pattern part PW overlapping the folding area FA.

The pattern part PW may include a recessed region CP recessed in a direction toward the base substrate VL-5 in the protection layer PF. According to an embodiment, the recessed region CP may have a concave shape in a cross-section in the first direction DR1. More specifically, the shape may include a valley G and a ridge M, which are arranged alternately in the first direction DR1. The valley G may have a convex shape protruding in the third direction DR3, and the ridge M may have a concave shape recessed in the third direction DR3. The recessed region CP may have a concave shape in a direction from the protection layer PF toward the base substrate VL as the valley G and the ridge M are alternately arranged. That is, for example, valleys G and ridges M may be alternately arranged along the concave shape in the recessed region CP.

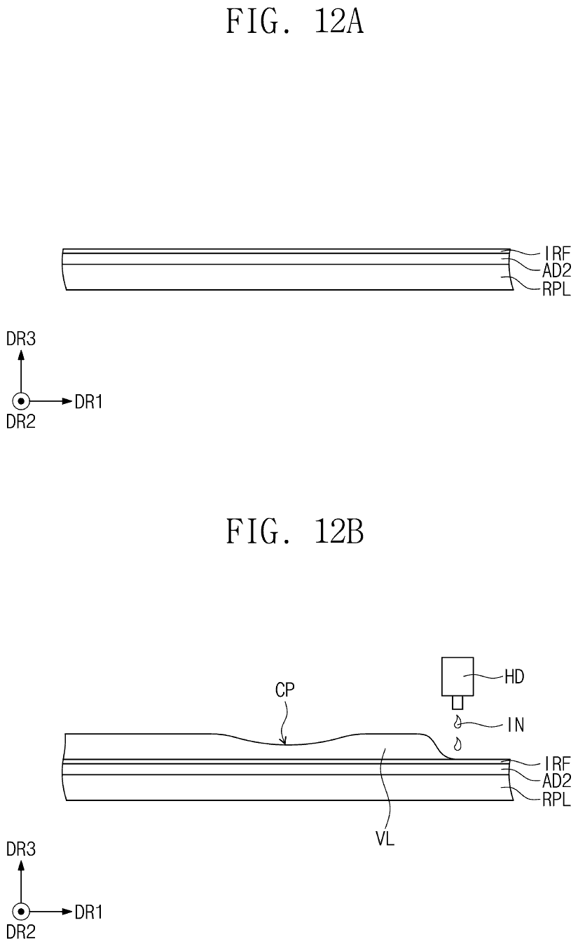

FIGS. 12A and 12B are cross-sectional views illustrating a method for manufacturing a display device according to an embodiment supported by the present disclosure. FIGS. 12A and 12B illustrate a process of forming the window WL-2 on the optical layer RPL, which is described in FIG. 8.

The method for manufacturing the display device according to an embodiment may include: a process of providing an optical layer to which an adhesive layer is attached; a process of performing a laminating process including adhering a transparent film to the adhesive layer; and a process of forming a coating layer including a pattern part having a concave shape by discharging an ink onto the transparent film. Here, the ink may include a transparent resin, and the pattern part may have a minimum thickness of 10 μm to 40 μm.

Referring to FIG. 12A, the method may include a process of providing an optical layer RPL. The method may include bonding a transparent film IRF to the optical layer RPL through a second adhesive layer AD2. The method may include bonding the transparent film IRF to the optical layer RPL through a laminating process. The transparent film IRF may include one of polyethylene terephthalate (PET) or transparent polyimide (CPI).

Thereafter, referring to FIG. 12B, the method may include a process of forming a coating layer VL on the transparent film IRF. The method may include forming the coating layer VL on the transparent film IRF, for example, by controlling a head HD such that the head HD discharges an ink IN while the head HD moves in the first direction DR1. The ink IN may include a transparent resin. The method may include applying (by discharging) the ink IN onto the transparent film IRF and then curing the ink IN.

Here, the coating layer VL may be formed to have a recessed region CP in which a portion overlapping the folding area FA (refer to FIG. 8) is recessed concavely. The coating layer VL may be formed through an inkjet process or a dispensing coating process. The ink IN may have high viscosity to form the recessed region CP by applying the transparent resin. The ink IN may have viscosity of 1000 cP to 2500 cP.

According to an embodiment, the optical layer RPL and the transparent film IRF may be laminated, and then the coating layer VL may be formed on the transparent film IRF.

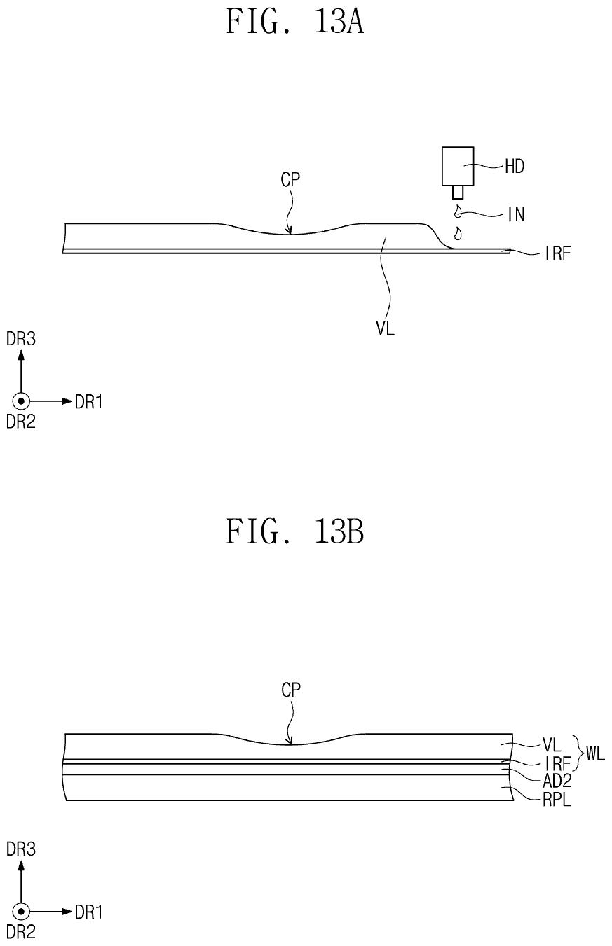

FIGS. 13A and 13B are cross-sectional views illustrating a method for manufacturing a display device according to an embodiment supported by the present disclosure. FIGS. 13A and 13B illustrate a process of forming the window WL-2 on the optical layer RPL, which is described in FIG. 8.

The method for manufacturing the display device according to an embodiment may include: a process of forming a coating layer including a pattern part having a concave shape by discharging an ink onto a transparent film; and a process of performing a laminating process including adhering the transparent film to an optical layer disposed below the transparent film through an adhesive layer. Here, the ink may include a transparent resin, and the ink may have a viscosity of 1000 cP to 2500 cP.

Referring to FIG. 13A, the method may include a process of forming a coating layer VL on a transparent film IRF. The transparent film IRF may include one of polyethylene terephthalate (PET) or transparent polyimide (CPI).

The method may include forming the coating layer VL on the transparent film IRF, for example, by controlling the head HD such that the head HD discharges an ink IN while the head HD moves in the first direction DR1. The ink IN may include a transparent resin. The coating layer VL may be formed through an inkjet process or a dispensing coating process. The method may include applying (by discharging) the ink IN onto the transparent film IRF and then curing the ink IN.

The ink IN may have high viscosity. Accordingly, for example, applying the ink IN (which includes the transparent resin) onto the transparent film IRF may form a recessed region CP. The ink IN may have viscosity of 1000 cP to 2500 cP.

Thereafter, referring to FIG. 13B, the method may include a process of forming a coating layer RPL on the transparent film IRF. The method may include bonding the transparent film IRF and the optical layer RPL to each other with a second adhesive layer AD2 between the transparent film IRF and the optical layer RPL through a laminating process.

According to an embodiment, after the process of forming the coating layer RPL on the transparent film IRF, the method may include performing the laminating process of bonding the optical layer RPL to the transparent film IRF.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

According to an embodiment supported by the present disclosure, the variable thickness of the pattern part included in the window may prevent cracks from occurring in the window during the folding operation of the display device. Thus, the display device having the improved folding characteristics may be provided.

In some aspects, as the base substrate of the window includes the transparent resin, the manufacturing costs for the window may be reduced.

Although example embodiments supported by aspects of the present disclosure have been described, it is understood that the present disclosure should not be limited to the example embodiments but various changes and modifications can be made by one ordinary skilled in the art within the spirit and scope of the present disclosure as hereinafter claimed. Hence, the real protective scope of the present disclosure shall be determined by the technical scope of the accompanying claims.

What is claimed is:

1. A display device comprising:
a display module comprising a folding area that is foldable based on a folding axis extending in a first direction, a first non-folding area, and a second non-folding area, wherein the first non-folding area and the second non-folding area are spaced apart from each other in a second direction crossing the first direction;
a window disposed on the display module; and
an optical layer disposed between the display module and the window,
wherein the window comprises:
a base substrate comprising a pattern part that overlaps the folding area, a first flat part that overlaps the first non-folding area, and a second flat part that overlaps the second non-folding area; and
a protection layer disposed on the base substrate,
wherein the pattern part comprises a recessed region recessed in a direction toward the base substrate from the protection layer.

2. The display device of claim 1, wherein the base substrate comprises a transparent resin.

3. The display device of claim 1, wherein:
the pattern part has a minimum thickness of about 10 μm to about 40 μm; and
each of the first flat part and the second flat part has a thickness of about 50 μm to about 100 μm.

4. The display device of claim 1, wherein the base substrate has a modulus of about 0.5 GPa to about 2 GPa.

5. The display device of claim 1, further comprising a first adhesive layer disposed between the protection layer and the base substrate,
wherein the first adhesive layer fills in the recessed region of the pattern part.

6. The display device of claim 1, wherein the recessed region of the pattern part is concave.

7. The display device of claim 6, wherein the recessed region of the pattern part has a cross-sectional shape comprising valleys and ridges connected to each other.

8. The display device of claim 1, wherein the recessed region of the pattern part comprises stepped portions that gradually descend in a direction toward a center of the pattern part from the first flat part and comprises stepped portions that gradually descend in a direction toward the center of the recessed region from the second flat part.

9. The display device of claim 1, further comprising a second adhesive layer disposed between the protection layer and the base substrate.

10. The display device of claim 9, wherein the base substrate comprises:
a transparent film disposed on the second adhesive layer; and
a coating layer disposed on the transparent film.

11. The display device of claim 10, wherein:
the transparent film comprises one of polyethylene terephthalate (PET) or transparent polyimide (CPI); and
the coating layer comprises a transparent resin.

12. The display device of claim 9, wherein the base substrate comprises a thin-film glass substrate disposed on the second adhesive layer.

13. The display device of claim 12, wherein the base substrate comprises a coating layer disposed on the thin-film glass substrate.

14. The display device of claim 1, wherein the base substrate directly contacts the optical layer.

15. The display device of claim 1, further comprising:
a lower film disposed below the display module;
a support plate disposed below the lower film; and
a lower plate disposed below the support plate.

16. The display device of claim 15, wherein the lower plate comprises holes that overlap the folding area and pass through the lower plate.

17. A method for manufacturing a display device, comprising:
providing an optical layer to which an adhesive layer is attached;
performing a laminating process comprising adhering a transparent film to the adhesive layer; and
forming a coating layer comprising a pattern part comprising a concave shape by discharging an ink onto the transparent film,
wherein the ink comprises a transparent resin, and the ink has viscosity of about 1000 cP to 2500 cP.

18. The method of claim 17, wherein the pattern part has a minimum thickness of about 10 μm to about 40 μm.

19. A method for manufacturing a display device, comprising:
forming a coating layer comprising a pattern part comprising a concave shape by discharging an ink onto a transparent film; and
performing a laminating process comprising adhering the transparent film to an optical layer disposed below the transparent film through an adhesive layer,
wherein the ink comprises a transparent resin, and the ink has viscosity of about 1000 cP to 2500 cP.

20. The method of claim 19, wherein the transparent film comprises one of polyethylene terephthalate (PET) or transparent polyimide (CPI).
